(19) United States
(12) Patent Application Publication
(10) Pub. No.: US 2026/0025124 A1
(43) Pub. Date: Jan. 22, 2026

(54) BULK ACOUSTIC WAVE FILTER

(71) Applicant: STMICROELECTRONICS INTERNATIONAL N.V., Geneva (CH)

(72) Inventor: Mohamed BOUFNICHEL, Monnaie (FR)

(21) Appl. No.: 19/259,648

(22) Filed: Jul. 3, 2025

(30) Foreign Application Priority Data
Jul. 17, 2024 (FR) FR2407822

(51) Int. Cl. H03H 9/56; H03H 3/02

(52) U.S. Cl. CPC H03H 9/564; H03H 3/02; H03H 2003/023

(57) ABSTRACT

The present disclosure provides a bulk acoustic wave filter. An example bulk acoustic waver filter is formed in and on a semiconductor substrate. The filter comprises: an air cavity buried in the semiconductor substrate; and at least one resonator formed in line with the air cavity, the resonator comprising an active layer sandwiched between bottom and top electrodes.

### CROSS REFERENCE TO RELATED APPLICATION(S)

This application claims the priority benefit of French Patent Application Number 2407822, filed on Jul. 17, 2024, entitled “Filtre à ondes acoustiques de volume,” which is hereby incorporated by reference to the maximum extent allowable by law.

### TECHNICAL FIELD

The present description relates generally to electronic devices, more particularly Bulk Acoustic Wave (BAW) filters.

### BACKGROUND

Numerous electronic devices comprise at least one bulk acoustic wave filter. For example, such filters are integrated in mobile phones, or smartphones, to avoid the operation of a receive channel of radiofrequency communications of the telephone to be disturbed by interferences caused by radiofrequency signals emitted by other electronic devices, or by noise from outer radiofrequency sources.

Two types of bulk acoustic wave filters have already been proposed: the so-called SMR (Solidly Mounted Resonator) filters on one side, and the so-called FBAR (thin-Film Bulk Acoustic Resonator) filters also referred to as “membrane” bulk acoustic wave filters, on the other side. A SMR filter conventionally comprises a membrane made of an insulating material located on, and in contact with, a Bragg mirror and a piezoelectric layer located on the membrane, and sandwiched between bottom and top electrodes. A FBAR filter differs from the SMR filter mainly in that in the case of the FBAR filter, the Bragg mirror is replaced with an air cavity above which the membrane is suspended. Providing the air cavity gives the FBAR filter a better efficiency than that of SMR filter. Indeed, the air cavity provides an acoustic insulation higher than that obtained with a Bragg mirror having several bilayers (around some fifteen bilayers would allow an insulation equivalent to that of an air cavity to be reached, that would be very difficult to practically implement), resulting in reduced energy losses.

However, existing acoustic wave filters, particularly existing FBAR filters, suffer from various drawbacks. FBAR filters are especially complicated and costly to implement, as the current manufacturing methods of such filters need an accurate control of the flatness of the structure, and implement a difficult step of forming the air cavity by removing a sacrificial layer. Furthermore, FBAR filters suffer from overheating and mechanical strength issues. Hence, it is difficult to miniaturize existing FBAR filters.

### BRIEF SUMMARY

There is a need to overcome some or part of the drawbacks of existing bulk acoustic wave filters, notably FBAR filters, and their manufacturing methods. It would particularly be desirable to simplify the methods for manufacturing such filters, and to be able to implement FBAR filters having higher mechanical strength and thermal performance than those of existing FBAR filters. It would allow to miniaturize more easily FBAR filters.

To this end, one embodiment provides a bulk acoustic wave filter formed in and on a semiconductor substrate, the filter comprising:
an air cavity buried in the semiconductor substrate; and
at least one resonator formed in line with the air cavity, each resonator comprising an active layer sandwiched between bottom and top electrodes.

According to one embodiment, the filter comprises a single resonator formed in line with the air cavity.

According to one embodiment, the filter comprises exactly first and second resonators formed in line with the air cavity.

According to one embodiment, top electrodes of the first and second resonators have different thicknesses.

According to one embodiment, the bottom electrodes of the first and second resonators form a common electrode.

According to one embodiment, each top electrode is asymmetrically-shaped, when viewed from above.

According to one embodiment, the semiconductor substrate is made of silicon.

According to one embodiment, each resonator is separated from the air cavity by a part of the semiconductor substrate having a thickness ranging from 300 nm to 1.5 μm.

One embodiment provides an electronic device, preferably a mobile phone or smartphone, comprising a radiofrequency integrated circuit including at least one filter as described.

One embodiment provides a method for manufacturing a bulk acoustic wave filter, the method comprising the following consecutive steps:
a) providing a semiconductor substrate;
b) forming an air cavity buried in the semiconductor substrate; and
c) forming at least one resonator in line with the air cavity, each resonator comprising an active layer sandwiched between bottom and top electrodes.

According to one embodiment, the method further comprises, between steps a) and b), a step of forming a plurality of hollow vias in the semiconductor substrate.

According to one embodiment, in step b), the air cavity is formed from the plurality of hollow vias by annealing the semiconductor substrate under hydrogen atmosphere.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a side, sectional, schematic, and partial view showing an example bulk acoustic wave filter;

FIG. 2 is a side, sectional, schematic, and partial view showing an example bulk acoustic wave filter according to one embodiment;

FIG. 3A, FIG. 3B, FIG. 3C, FIG. 3D, and FIG. 3E illustrate, with side, sectional, schematic, and partial views, structures obtained at the end of consecutive steps of a method for manufacturing the bulk acoustic wave filter shown in FIG. 2 according to one embodiment;

FIG. 4 is a side, sectional, schematic, and partial view showing an example bulk acoustic wave filter according to one embodiment; and

FIG. 5 is a side, sectional, schematic, and partial view showing an example device integrating a bulk acoustic wave filter.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, integrating bulk acoustic wave filters in the various electronic devices likely to implement such filters was not described in detail, the embodiments described being compatible with all or most of the electronic devices integrating at least one filter, optionally subject to adaptations within the capabilities of those skilled in the art upon reading the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or within 10°, and preferably within 5% or within 5°.

Unless specified otherwise, in the following description, the “insulating” and “conductive” qualifiers respectively mean electrically insulating and electrically conductive.

Unless specified otherwise, the term “in contact with” means “in mechanical contact with”.

FIG. 1 is a side, sectional, schematic, and partial view showing an example bulk acoustic wave filter 100. For example, filter 100 is more specifically of the “FBAR” (“thin-Film Bulk Acoustic Resonator”) type or “membrane” bulk acoustic wave filter.

In the example shown, filter 100 comprises a semiconductor substrate 101, e.g. a wafer or a piece of wafer made of a semiconductor substrate. As an example, the semiconductor substrate 101 is made of silicon.

In the example shown, filter 100 further comprises an insulating layer 103 coating a top face 101T of the semiconductor substrate 101. In the example shown, the insulating layer 103 is located in, and in contact with, the whole top face 101T of the semiconductor substrate 101. For example, the insulating layer 103 has a thickness ranging from 1.3 to 4 μm. As an example, the insulating layer 103 is made of an oxide, such as silicon oxide. For example, the insulating layer 103 acts as a passivating layer for the top face 101T of the semiconductor substrate 101.

In the example shown, filter 100 further comprises a cavity formed in the insulating layer 103. For example, cavity 105 has a height strictly less than the thickness of the insulating layer 103, and lateral dimensions strictly less than those of the insulating layer 103. In this example, the walls of the cavity 105 are formed by the material of the insulating layer 103. For example, cavity 105 has a height ranging from 0.3 to 2 μm. As an example, cavity 105 is filled with air. In the example shown, cavity 105 has sidewalls substantially straight-lined and substantially vertical. In this example, cavity 105 is substantially rectangularly shaped, in sectional view.

In the example shown, filter 100 further comprises an electrode 107 coating a part of the top face of the insulating layer 103. In the example shown, electrode 107 is located on, and in contact with, a part of the top face of the insulating layer 103. Electrode 107 is at least in part located in line with the cavity 105. As in the example illustrated in FIG. 1, electrode 107 is for example mostly located in line with the cavity 105. In this example, electrode 107 further comprises a minority part laterally extending out in line with the cavity 105. As an example, electrode 107 is made of a conductive material, for example a metal such as aluminum or a metal alloy.

In the example shown, filter 100 further comprises another insulating layer 109 coating the side faces and top face of electrode 107. In this example, the insulating layer 109 further coats parts of the top face of the insulating layer 103 not coated with the electrode 107. In other words, the insulating layer 109 laterally extends out in line with electrode 107. For example, insulating layer 109 is more specifically located on, and in contact with, the side and top faces of the electrode 107 and the parts of the top face of the insulating layer 103 not coated with the electrode 107. As an example, the insulating layer 109 is a piezoelectric layer, i.e. a layer made of a piezoelectric material, e.g. Lithium Niobate Oxide (LNO), aluminum nitride, etc.

In the example shown, filter 100 further comprises another electrode 111 coating a part of the top face of the insulating layer 109. In the example shown, electrode 111 is located on, and in contact with, a part of the top face of the insulating layer 109. For example, electrode 111 is at least in part located in line with cavity 105. As in the example illustrated in FIG. 1, electrode 111 is mostly located in line with the cavity 105. In this example, electrode 111 has lateral dimensions strictly less than those of electrode 107. For example, electrodes 111 and 107 are top and bottom electrodes of filter 100, respectively. As an example, electrode 111 is made of a conductive material, for example a metal such as aluminum or a metal alloy. For example, electrode 111 is made of a same material as electrode 107.

Electrode 111 is for example asymmetrically-shaped, when viewed from above.

In the example shown, filter 100 further comprises yet another insulating layer 113 coating the side faces and top face of electrode 111. In this example, the insulating layer 113 further coats parts of the top face of the insulating layer 109 not coated with the electrode 111. For example, insulating layer 113 is more specifically located on, and in contact with, the side and top faces of the electrode 111, and with the parts of the top face of the insulating layer 109 not coated with the electrode 111. As an example, the insulating layer 113 is made of an oxide, for example silicon oxide. For example, the insulating layer 113 is made of a same material as insulating layer 103. For example, the insulating layer 113 acts as a passivating layer for the top face of the structure, particularly for electrode 111.

In the example shown, filter 100 further comprises contact pick-up elements 115 and 117 of electrodes 107 and 111, respectively. In the example illustrated in FIG. 1, the contact pick-up element 115 is located on, and in contact with, a part of the top face of electrode 107 located out in line with cavity 105. When viewed in section, the contact pick-up element 115 has for example a T-like shape comprising a vertical part extending, from the top face of the insulating layer 113, through the insulating layers 113 and 109 to the top face of electrode 107 and a horizontal part laterally extending on, and in contact with, the top face of the insulating layer 113 in the vicinity of the vertical part of the contact pick-up element 115.

Furthermore, in this example, the contact pick-up element 117 is located on, and in contact with, a part of the top face of the electrode 111 located in line with cavity 105. When viewed in section, the contact pick-up element 117 has for example a T-like shape comprising a vertical part extending, from the top face of the insulating layer 113, through the insulating layer 113 to the top face of electrode 111 and a horizontal part laterally extending on, and in contact with, the top face of the insulating layer 113 in the vicinity of the vertical part of the contact pick-up element 117. Each contact pick-up element 115, 117 is made of a conductive material, for example a metal or a metal alloy. As an example, the contact pick-up elements 115, 117 are made of a same material.

Although it was not illustrated in FIG. 1 in order not to overload the drawing, the contact pick-up elements 115, 117 are for example intended to be coupled, or connected, to one or more components or circuits out the filter 100. As an example, the contact pick-up elements 115, 117 are intended to be connected to a radiofrequency communication circuit of an electronic device.

In the example shown, filter 100 further comprises an opening 119 located in line with cavity 105. In this example, opening 119 extends from the top face of the insulating layer 113, through the insulating layers 113 and 109, and through a part of the insulating layer 103 not coated with electrode 107, and vertically extending between the top face of the insulating layer 103 and the top face of cavity 105. In the example shown, cavity 119 forms an opening in cavity 105. For example, opening 119 is a via formed to allow a sacrificial layer previously formed in the insulating layer 103 to be retrieved so that cavity 105 is implemented. The sacrificial layer is for example made of silicon.

In the example shown, filter 100 comprises a membrane suspended above cavity 105, and made of a part of the insulating layer 103 located in line with electrode 111, and sandwiched between the top face of cavity 105 and the top face of the insulating layer 103. For example, filter 100 comprises an active area made of parts of electrode 111, insulating layer 109, electrode 107, and insulating layer 103 located above cavity 105 and in line with electrode 111.

Electrodes 107 and 111 and the part of the insulating layer 109 sandwiched between electrodes 107 and 111 are for example part of a resonator 121 of filter 100. For example, insulating layer 109 referred to as active area of the resonator 121 of filter 100, due to the fact the insulating layer 109 is intended to be energized by a signal applied on the electrodes 107 and 111 located either side of this layer.

In operation, a radiofrequency signal is for example applied, by the contact pick-up elements 115 and 117, across electrodes 107 and 111 of filter 100. The radiofrequency signal is for example an AC voltage. Applying, on electrodes 107 and 111, the radiofrequency signal for example causes alternating expansion and contraction phases of the insulating layer 109. It tends the resonator 121 of filter 100 to resonate, and the membrane of filter 100 to vibrate. In the case where the radiofrequency signal has a frequency substantially equal to a resonance frequency of the membrane of filter 100, the radiofrequency signal is not, or little, attenuated by filter 100. By contrast, in the case where the radiofrequency signal has a frequency different from the resonance frequency of the membrane of filter 100, the radiofrequency signal is highly attenuated by filter 100. For example, it allows avoiding the operation of the radiofrequency communication receive channel to be disturbed with interferences due to radiofrequency signals emitted by other electronic devices or by noise coming from outer radiofrequency sources.

A drawback of the bulk acoustic wave filter 100 lays in that its active area is separated from semiconductor substrate 101 by a part of the insulating layer 103 vertically extending from the bottom face of electrode 107 to the top face 101T of the semiconductor substrate 101 (the part of the insulating layer 103 located on left side of cavity 105, in the orientation shown in FIG. 1).

Insulating layer 103 being made of a material having a low thermal conductivity, typically lower than that of the substrate 101, it consequently impairs evacuating calories produced by the active area of filter 100 as the membrane vibrates. It results in an unwanted overheating of the active area of filter 100, which tends to degrade the performance.

Another drawback of filter 100 lays in providing cavity 105 and through opening 119. Hence, filter 100 has a relatively low mechanical strength. Furthermore, materials of semiconductor substrate 101 and insulating layer 103 have different thermal expansion coefficients, which also tends to weaken the structure due to temperature variations related to operation of filter 100.

Further, a drawback of filter 100 comes from the fact that forming the cavity 105 by removing a sacrificial layer constitutes a step especially difficult to implement. Furthermore, requirements of flatness of the insulating layers 103, 109, and 113, and of the electrodes 107 and 111 would complicate the implementation of filter 100.

Abovementioned drawbacks result in limiting the use of bulk acoustic wave filters such as filter 100 previously described in reference to FIG. 1 and interfere with miniaturizing such filters.

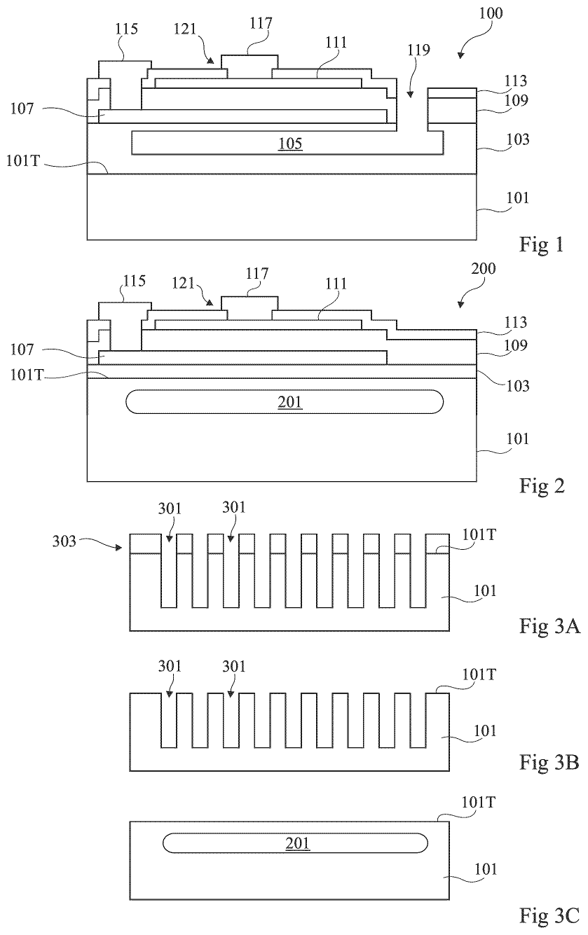

One embodiment allowing at least in part these drawbacks to be overcome is described in detail in reference to FIG. 2.

FIG. 2 is a side, sectional, schematic, and partial view showing an example bulk acoustic wave filter 200 according to one embodiment. For example, filter 200 is more specifically a FBAR filter.

Filter 200 shown in FIG. 2 comprises elements in common with filter 100 shown in FIG. 1. These common elements will not be again described in detail hereinafter.

Filter 200 shown in FIG. 2 differs from filter 100 shown in FIG. 1 in that it is devoid of cavity 105 formed in the insulating layer 103 and opening 119. According to one embodiment, filter 200 comprises a buried, or covered, air cavity 201 in the semiconductor substrate 101. According to this embodiment, cavity 201 is entirely contained in the semiconductor substrate 101. Cavity 201 is thus wholly closed.

In the example shown, cavity 201 is entirely bordered with the material of semiconductor substrate 101. In this example, cavity 101 is separated from the substantially flat top face 101T of the semiconductor substrate 101 by a part of the semiconductor substrate 101. For example, cavity 201 is located at a depth ranging from a few hundred nanometer to a few micrometers under the top face 101T of the semiconductor substrate 101. In other words, the top face of cavity 201 is separated from the top face of the semiconductor substrate 101 by a part of substrate 101 having a thickness for example ranging from a few hundred nanometer to a few micrometers. The thickness of the part of substrate 101 sandwiched between the top face of cavity 201 and the top face 101T of the semiconductor substrate 101 for example ranges more specifically from 300 nm to 1.5 μm.

In the example shown, cavity 201 comprised rounded or curved flanks being concavely shaped. As an example, each flank of the cavity 201 has, when viewed in section, a circular arc shape, for example a semicircle shape.

When viewed from above, cavity 201 is for example rectangularly shaped. This example is however not a limitation, as the cavity 201 could more generally have, when viewed from above, any shape, for example the shape of a polygon other than a rectangle—such as a square, a triangle, a hexagon, etc.—or a rounded shape—such as an oval, a circle, etc.

Electrode 107 is at least in part located in line with cavity 201. For example, as in example shown in FIG. 2, electrode 107 is mainly located in line with cavity 201. In this example, electrode 107 further comprises a minority part laterally extending out in line with cavity 201.

Furthermore, electrode 111 is at least partially located in line with cavity 201, for example. For example, as in example shown in FIG. 2, electrode 111 is entirely located in line with cavity 201. In this example, electrode 107 has lateral dimensions strictly less than those of electrode 107.

In the example shown in FIG. 2, the contact pick-up element 115 is located on, and in contact with, a part of the top face of electrode 107 located out in line with cavity 201. It allows avoiding, or restricting, disturbances of the resonator 121 of filter 200 with respect to a case where the contact pick-up element 115 would be in contact with a part of the top face of the electrode 107 located in line with cavity 201.

In the case of filter 200, the membrane of resonator 121 is formed of a part of the semiconductor substrate 101 sandwiched between the cavity 201 and the top face 101T of the substrate 101 and located in line with electrode 111.

Although it was not shown in FIG. 2, filter 200 could further include a protective cap of the resonator 121 of filter 200, for example a cap standing on the top face 101T of the substrate 101, and inside which are located the electrodes 107 and 111 and the insulating layers 109 and 113 of filter 200. Implementing such a protective cap is within the capabilities of those skilled in the art from the indications of the present disclosure.

On the assumption that filter 200 is, contrary to filter 100, devoid of cavity 105 located in the insulating layer 103, the insulating layer 103 of filter 200 for example has a thickness highly less than that of the insulating layer 103 of filter 100. As an example, the insulating layer 103 has in the case of filter 200, a thickness ranging from 0.5 to 1.5 μm, for example equal to 0.8 μm. It advantageously allows heat dissipation of the resonator 121 of filter 200 to be improved in comparison to filter 100. Heat dissipation is further facilitated due to the fact that the flanks of cavity 201 is round-shaped.

Another advantage of filter 200 comes from the fact that cavity 201 is located in the semiconductor substrate 101. It provides to the filter 200 a mechanical strength higher than that of filter 100. The fact that filter 200 is devoid of opening 1119 further contributes to improve the mechanical strength in comparison to the filter 100.

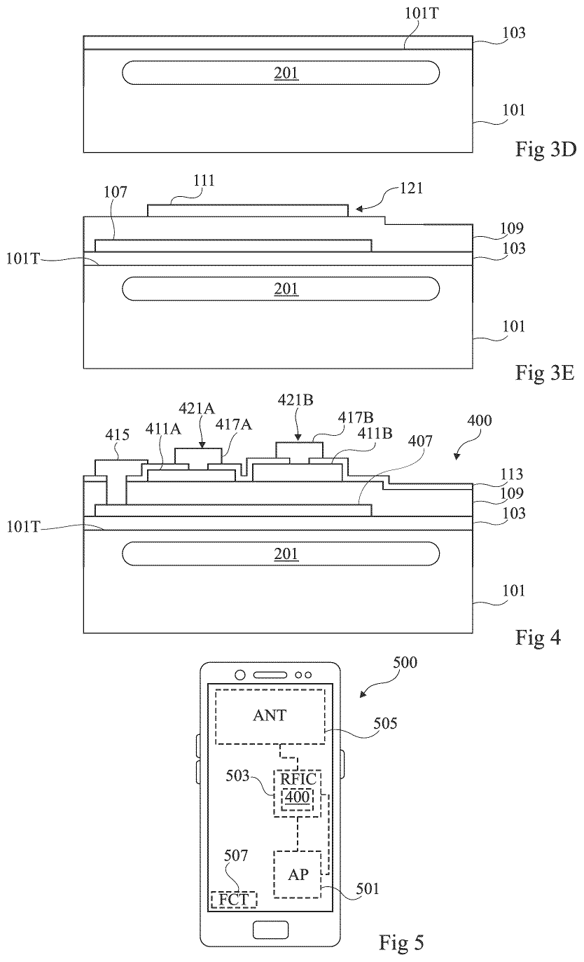

FIG. 3A, FIG. 3B, FIG. 3C, FIG. 3D, and FIG. 3E illustrate, with side, sectional, schematic, and partial views, structures obtained at the end of consecutive steps of a method for manufacturing the bulk acoustic wave filter 200 shown in FIG. 2 according to one embodiment.

FIG. 3A illustrates a structure obtained at the end of a step of forming a plurality of hollow vias 301 in the semiconductor substrate 101.

In the example shown, hollow vias 301 extend from the top face 101T of the semiconductor substrate 101 to a depth less than the thickness of substrate 101. In other words, hollow vias 301 are blind and do not open on the side of the bottom face of the semiconductor substrate 101.

When viewed from above, each hollow via 301 has for example a section with a substantially square shape. However, this example is not a limitation, each via 301 being able to generally have, when viewed from above, ay shape, for example a shape of a polygon other than square—e.g. rectangle, triangle, hexagon, etc.—or a rounded shape, e.g. oval, circular, etc. As an example, the hollow vias 301 have shapes and dimensions substantially identical, within manufacturing dispersions. For example, hollow vias 301 have particularly a same depth, within manufacturing dispersions.

For example, hollow vias 301 are arranged in array according to lines and columns. For example, lines are substantially perpendicular to columns. For example, the array formed by the hollow vias 301 have within manufacturing dispersions a substantially fixed pitch, i.e. a substantially fixed center-to-center distance between two neighboring vias.

For example, hollow vias 301 are implemented by photolithography then etching. To this end, a photosensitive resin layer 303 is for example deposited on the side of the top face 101T of the semiconductor substrate 101. For example, the photosensitive resin layer 303 coats the whole top face of the semiconductor substrate 101. In the example shown, the photosensitive resin layer 303 is more specifically located on, and in contact with, the top face 101T of the semiconductor substrate 101.

For example, through opening are then formed in the photosensitive resin layer 303 at wanted locations of the future hollow vias 301, for example by insolating the photosensitive resin layer 303 through a mask and removing insolated parts of the layer 303, in the case of a positive resin, or non-insolated parts of the layer 303, in the case of a negative resin.

Once the openings are formed in the photosensitive resin layer at the wanted locations of the future hollow vias 301, the opening are then for example extended in the semiconductor substrate 101 by etching, e.g. by Reactive Ion Etching (RIE), such as Deep Reactive Ion Etching (DRIE).

FIG. 3B illustrates a structure obtained at the end of a further step of removing the photosensitive resin layer 303.

In the example shown in FIG. 3B, the photosensitive resin layer 303 is entirely removed.

FIG. 3c illustrates a structure obtained at the end of a further step of annealing the semiconductor substrate 101 inside which were previously formed the hollow vias 301.

In the example shown, annealing results in forming the cavity from the hollow vias 301. Annealing is for example implemented at a temperature of the order of 1.000° C., for example ranging from 1,000° C. and 1,150° C. For example, annealing is further implemented under hydrogen atmosphere, in the case where the semiconductor substrate 101 is made of silicon. The fact of annealing under hydrogen allows the silicon atoms of the semiconductor substrate 101 to have a surface mobility higher than in lack of hydrogen.

Under annealing action, the silicon atoms of the semiconductor substrate 101 reorder so that the structure has minimum surface roughness and surface energy without bulk loss. Practically, the hollow vias tend to flare in bottom part, i.e. in the vicinity of their bottom, and to obtrude in top part, i.e in the vicinity of the top part 101T of the semiconductor substrate 101. Due to these phenomena, the hollow vias 301 gradually transform into cavity 201 as was illustrated in FIG. 3C. The bottom of the cavity 201 is located, in the semiconductor substrate 101, at a depth strictly less than that of the bottom of the hollow vias 301.

AS an example, those skilled in the art will be able, in order to implement the step previously mentioned in reference to FIGS. 3A-3C, to take inspiration from that has been described in the publication of I. Mizushima et al. titled “Empty-space-in-silicon technique for fabricating a silicon-on-nothing structure” published in November 200 in the review Applied Physics Letters.

FIG. 3D illustrates a structure obtained at the end of a further step of depositing the insulating layer 103 on the side of the top face 101T of the semiconductor substrate 101.

In the example shown, the insulating layer 103 coats the whole top face 101T of the semiconductor substrate 101. Insulating layer 103 is for example more specifically located on, and in contact with, the whole top face 101T of the semiconductor substrate 101.

FIG. 3E illustrates a structure obtained at the end of a further step of implementing the resonator 121.

During this step, electrode 107, active layer 109, and electrode 111 are consecutively formed, in this order, on the face 101T of the semiconductor substrate 101. Electrode 107 is for example formed by depositing a conductive layer on the top face of the insulating layer 103, and by patterning, for example by photolithography then etching, the conductive layer so as to keep only a part of the conductive layer corresponding to electrode 107.

For example, the insulating layer 109 is then deposited on the whole top face of the structure.

For example, the electrode 111 is then implemented in a same or analogous way the electrode 107 has been implemented, for example by depositing a conductive layer on the top face of the insulating layer 109 and by patterning, for example by photolithography then etching, the conductive layer so as to keep only a part of the conductive layer corresponding to electrode 111.

Although it was not shown, the insulating layer 113 is for example then deposited on the whole top face of the structure.

The contact pick-up elements 115 and 117 are then formed by opening the insulating layers 113 and 109 in line with electrode 107, for the contact pick-up element 115, and by opening the insulating layer 113 in line with electrode 111, for the contact pick-up element 117. For example, a conductive layer filling the opening is then deposited on the whole top face of the structure, and patterned for example by photolithography then etching, so as to keep only parts of the conductive layer corresponding to the contact pick-up elements 115 and 117. As a variant, locally depositing a conductive material could be provided. For example, filter 200 is thus obtained.

FIG. 4 is a side, sectional, schematic, and partial view showing an example bulk acoustic wave filter 400 according to one embodiment. The filter 400 shown in FIG. 4 comprises elements in common with the filter 200 shown in FIG. 2. These common elements will not be again described in detail hereinafter.

The filter 400 shown in FIG. 4 differs from the filter 200 shown in FIG. 2 in that the filter 400 comprises two resonators 421A and 421B located above and in line with the cavity 201.

In the example shown, filter 400 comprises an electrode 407 coating a part of the top face of the insulating layer 103. In the example shown, electrode 407 is located on, and in contact with, a part of top face of the insulating layer 103. Electrode 407 is at least in part located in line with the cavity 201. As in the example shown in FIG. 4, electrode 407 is for example mainly located in line with cavity 201. In this example, electrode 407 further comprises a minority part laterally extending out in line with cavity 201. For example, electrode 407 is analogous or identical to electrode 107 of the filter 200. As an example, electrode 407 is made of a conductive material, for example a metal such as aluminum or a metal alloy.

For example, electrode 407 constitutes a bottom electrode common to two resonators 421A and 421B of filter 400. It allows to make simpler the implementation of the filter 400. However, this example is not a limitation, and those skilled in the art may as a variant provide that each resonator 421A, 421B of filter 400 includes a bottom electrode insulated from that of the other resonator 421B, 421A.

Active layer 109 coats the electrode 407 of the filter 400. In the example shown, the active layer 109 is more specifically located on, and in contact with, the side and top walls of the electrode 109. Furthermore, in this example, electrode 407 is common with the two resonators 421A and 421B of the filter 400. It allows to make simpler the implementation of the filter 400. However, this example is not a limitation, and those skilled in the art could as a variant provide that each resonator 421A, 421B of the filter 400 includes an active layer separate from that of the other resonator 421B, 421A.

In the example shown, each resonator 421A, 421B of the filter 400 further comprises another electrode 411A, 411B coating a part of the top face of the active layer 109. In the example shown, each electrode 411A, 411B is located on, and in contact with, a part of the top face of the active layer 109. For example, electrodes 411A and 411B are at least in part located in line with cavity 201. As in the example shown in FIG. 4, each electrode 411A, 411B is for example entirely located in line with cavity 201. In this example, each electrode 411A, 411B has side dimensions strictly less than those of the electrode 407. For example, electrodes 411A and 411B constitute top electrodes of filter 400. As an example, each electrode 411A, 411B is made of a conductive material, for example a metal such as aluminum or a metal alloy. For example, electrodes 411A and 411B are made of the same material as electrode 407.

For example, each electrode 411A, 411B is asymmetrically shaped when viewed from above.

According to one embodiment, one of the electrodes 411A, 411B has a thickness different from that of the other electrode 411B, 411A. In the example shown, electrode 411A (located on the left, in the orientation shown in FIG. 4) has a thickness less than that of electrode 411B (located on the right, in the orientation shown in FIG. 4). However, this example is not a limitation and those skilled in the art could as a variant provide that the electrode 411A has a thickness strictly higher than that of the electrode 411B.

In the example shown, the filter 400 further comprises the contact pick-up elements 415, 417A, and 417B of the electrodes 407, 411A, and 411B, respectively. In the example shown in FIG. 4, the contact pick-up element 415 is located on, and in contact with, a part of the top face of the electrode 407 located out in line with cavity 201. For example, when viewed in section, the contact pick-up element 415 has a T-like shape comprising a vertical part extending, from the top face of the insulating layer 113, through the insulating layers 113 and 109 to the top face of the electrode 407, and a horizontal part laterally extending on, and in contact with, the top face of the insulating layer 113 in the vicinity of the vertical part of the contact pick-up element 415.

Furthermore, in this example, the contact pick-up element 417A, 417B is located on, and in contact with, a part of the top face of the electrode 411A, 411B located in line with cavity 201. For example, the contact pick-up element 417A, 417B has when viewed in section, a T-like shape comprising a vertical part extending from the top face of the insulating layer 113 through the insulating layer 113 to the top face of electrode 411A, 411B and a horizontal part laterally extending on, and in contact with, the top face of the insulating layer 113 in the vicinity of the vertical part of the contact pick-up element 417A, 417B. Each contact pick-up element 415, 417A, and 417B is made of a conductive material, for example a metal or an alloy metal. As an example, the contact pick-up elements 417A and 417B are made of the same material as the contact pick-up element 415.

Although it has not been shown in FIG. 4 in order not to overload the drawing, the contact pick-up elements 415, 417A, and 417B are for example intended to be coupled, or connected, to one or more components or circuits out the filter 400. As an example, the contact pick-up elements 415, 417A, and 417B are intended to be connected to a radiofrequency communication circuit of an electronic device.

The fact of providing the electrodes 411A and 411B having different thicknesses allows the resonators 421A and 421B to have different resonance frequencies. In such case, the filter 400 is for example a bandpass filter, for example a filter letting through signals having a frequency comprised in a frequency band substantially delimited by the resonance frequencies of the resonators 421A and 421B. As an example, the bandwidth of the filter 400 is in the order of gigahertz, for example ranging from 0.5 to 6 GHz.

Filter 400 has analogous advantages as those previously described in reference to FIG. 2 as regards filter 200, particularly in terms of thermal performance and of mechanical strength.

FIG. 5 is a side, sectional, schematic, and partial view showing an example device 500 integrating a bulk acoustic wave filter, for example filter 400 previously described in reference with FIG. 4. In the example shown, device 500 is a mobile phone or smartphone.

In this example, device 500 comprises a processing circuit 501 (AP), for example a microcontroller or a main microprocessor of the device 500. For example, processing circuit 501 is connected to a radiofrequency integrated circuit (RFIC) comprising at least one filter of the type of filter 200 or 400, for example a filter 400. Filter 400 is for example integrated in an electronic filter circuit, not shown in detail in FIG. 5. In the example shown, the radiofrequency integrated circuit 503 is connected to an antenna 505 (ANT), for example a radiofrequency communication antenna of the device 500. Although it was not shown in detail in FIG. 5 in order not to overload the drawing, the radiofrequency integrated circuit 503 could further comprise components and circuits intended to implement functions of impedance matching, amplifying, modulating/demodulating, switching, etc.

Device 500 could further comprise other elements, for example other electronic components or circuits not described in detail in FIG. 5. These elements were symbolized in FIG. 5 by a functional block 507 (FCT).

Although FIG. 5 illustrates a case wherein filter 400 is integrated in the device 500, this example is not a limitation and those skilled in the art will be able to provide, based on the indications of the present disclosure, replacing, in device 500, the filter 400 with the filter 200 or with a filter having a structure analogous to that of filter 200 or 400.

Various embodiments and variants have been described. Those skilled in the art will understand that certain features of these embodiments can be combined and other variants will readily occur to those skilled in the art. In particular, although FIG. 4 considers as an example a case in which the filter 400 comprises two resonators 421A and 421B located above the cavity 201, those skilled in the art will of course be able, based on the indications of the present disclosure, to adapt the embodiment shown in FIG. 4 to any number of resonators located above a same cavity implemented in a semiconductor substrate.

Based on the indications of the present disclosure, those skilled in the art will further be able to implement several filters in a same semiconductor substrate, for example by providing to form several buried cavities in a same semiconductor substrate and at least one resonator located in line with each cavity.

Furthermore, although FIG. 5 considers as an example the case of integrating of filter 400 in a mobile phone or a smartphone, the embodiments described do not limit to this example but more generally apply to any device or system equipped with functions of wireless communication, for example in the field of telematic. In particular, filter 400 or filter 200 may be integrated in automotive vehicles, for example to implement functions of wireless Internet access, communication of the vehicle with outer equipment or systems, autonomous driving, etc. for end applications such as managing vehicle fleets (location, movement, state, and behavior of each vehicle) or the real-time navigation systems, or yet to allow things to communicate with a vehicle (for example in the context of Internet of Things-IoT), anything without interferences from non-trusted systems in a “circle” of trusted communications.

Finally, the practical implementation of the embodiments and variants described herein is within the capabilities of those skilled in the art based on the functional description provided hereinabove. In particular, implementing the filter 400 is within the capabilities of those skilled in the art when reading the present disclosure, particularly based on the method for manufacturing the filter 200 described in reference to FIGS. 3A-3E.

Furthermore, the embodiments described are not limited to the specific examples of materials and dimensions mentioned in the present disclosure.

1. A bulk acoustic wave filter formed in and on a semiconductor substrate, the filter comprising:
an air cavity buried in the semiconductor substrate; and
at least one resonator formed in line with the air cavity, each resonator comprising an active layer sandwiched between bottom and top electrodes.

2. The bulk acoustic wave filter of claim 1, comprising a single resonator formed in line with the air cavity.

3. The bulk acoustic wave filter of claim 1, comprising exactly a first resonator and a second resonator formed in line with the air cavity.

4. The bulk acoustic wave filter of claim 3, wherein top electrodes of the first resonator and the second resonator have different thicknesses.

5. The bulk acoustic wave filter of claim 3, wherein the bottom electrodes of the first resonator and the second resonator form a common electrode.

6. The bulk acoustic wave filter of claim 1, wherein each top electrode is asymmetrically-shaped, when viewed from above.

7. The bulk acoustic wave filter of claim 1, wherein the semiconductor substrate is made of silicon.

8. The bulk acoustic wave filter of claim 1, wherein each resonator is separated from the air cavity by a part of the semiconductor substrate having a thickness ranging from 300 nm to 1.5 μm.

9. An electronic device comprising a radiofrequency integrated circuit including at least one bulk acoustic wave filter of claim 1.

10. The electronic device of claim 9, wherein the electronic device is a mobile phone or a smartphone.

11. A method for manufacturing a bulk acoustic wave filter, the method comprising the following consecutive steps:
a) providing a semiconductor substrate;
b) forming an air cavity buried in the semiconductor substrate; and
c) forming at least one resonator in line with the air cavity, each resonator comprising an active layer sandwiched between bottom and top electrodes.

12. The method of claim 11 further comprising, between steps a) and b), a step of forming a plurality of hollow vias in the semiconductor substrate.

13. The method of claim 12, wherein in step b), the air cavity is formed from the plurality of hollow vias by annealing the semiconductor substrate under hydrogen atmosphere.
